(19) United States
(12) Patent Application Publication
(10) Pub. No.: US 2006/0094204 A1
(43) Pub. Date: May 4, 2006

(54) Planarization material, anti-reflection coating material, and method for manufacturing semiconductor device thereby

(75) Inventor: Shunsuke Isono, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/258,995

(22) Filed: Oct. 27, 2005

(30) Foreign Application Priority Data
Nov. 2, 2004 (JP) 2004-319649

(51) Int. Cl. H01L 21/76

(52) U.S. Cl. 438/437

(57) ABSTRACT

A material including a photo acid generator or thermal acid generator is used to at least one of a planarization material for a chemically amplified resist film and an anti-reflection coating film material applied under the chemically amplified resist film. In case of the photo acid generator, acid substances are generated by a flood exposure, and in case of the thermal acid generator, acid substances are generated by a heating. Therefore, it is possible to block reaction inhibitors causing a defective resolution of a resist pattern.

### RELATED APPLICATION

The present application claims the benefit of priority from Japan Patent Application No. 2004-319649, entitled “PLANARIZATION MATERIAL, ANTI-REFLECTION COATING MATERIAL, AND METHOD FOR FORMING SEMICONDUCTOR DEVICE THEREBY”, filed on Nov. 2, 2004.

### FIELD OF THE INVENTION

The present invention generally relates to a planarization material, a anti-reflection coating material, and a method for manufacturing a semiconductor device by using those materials, and more specifically, to the planarization material and anti-reflection coating material suitable for manufacturing the semiconductor device with a damascene structure, and the method for manufacturing the semiconductor device by using those materials.

### DESCRIPTION OF RELATED ART

Recently, for the purpose of the improvement of working speed and the power consumption saving, it is rapidly advancing the sub-miniaturization and high integration of the semiconductor integrated circuit. In developing of the sub-miniaturization and the high integration, the wiring resistance and the parasitic capacitance become large in the multi-level structure wiring for interconnecting devices of the integrated circuit, and the delay time of the wiring becomes factors to limit the speed-up of the integrated circuit.

As a countermeasure against the above-mentioned problem, the multi-level structure wiring tends to adopt as a wiring material a copper of which resistivity is lower than the aluminum of a conventional use, and also adopt as an inter-layer dielectric various organic and inorganic low-dielectric-constant materials (FIG. 3).

Since the copper used as the wiring material is difficult to be etched, a following process is used to form the multi-level structure wiring; the copper is embedded in a trench pattern formed on an insulating film, and then the surface of the copper wiring is planarized by the Chemical Mechanical Polishing (CMP), which is called a damascene process.

The damascene process is discussed here according to drawings. FIGS. 4A to 4H show the damascene process illustrating sectional views of each step. The process shown in FIGS. 4A to 4H is a process for forming a through-hole before a trench patter is formed, the through-hole interconnecting a formed wiring on a layer under the insulating film to form the trench pattern thereon and a wiring to be embedded in the trench pattern, and then simultaneously embedding the copper in both the through-hole and the trench pattern. This is a process for forming a via-first dual-damascene structure.

As shown in FIG. 4A, a copper wiring 2 is embedded in a first wiring layer 21 by means of a conventional integration processing technology, whereby a first insulating film 1 is formed on a semiconductor substrate 20.

As shown in FIG. 4B, following films are deposited on the first wiring layer 21 by a chemical vapor deposition (CVD) in this order; an etch-stop film 3 of silicon carbon nitride (SiCN) film, a second insulating film 4 of a carbon-dropped silicon dioxide (SiOC) film, and a cap film 5 of silicon dioxide (SiO₂) film, the second insulating film 4 is composed of a low dielectric constant film of which dielectric constant is 3 or less. Additionally, an anti-reflection coating 6 and a photoresist 7 are applied on the surface of the cap film 5 sequentially.

Next, a resist pattern 7a with openings for forming through-holes 8 is formed by the conventional lithography, as shown in FIG. 4C. The through-holes 8 interconnects the copper wirings 2 in the first wiring layer 21 and the copper wiring in a layer over the first wiring layer 21.

Moreover, as shown in FIG. 4D, the anti-reflection coating 6, the cap film 5, and the second insulating film 4 are sequentially etched using the resist pattern 7a as an etching mask by the conventional dry etching, and the through-holes are formed. After the dry etching, the resist pattern 7a used as the etching mask and the anti-reflection coating 6 are removed by the ashing and the organic cleaning.

Next, to form the copper wiring on the second insulating film 4 and the cap film 5, a following process is performed.

As shown in FIG. 4E, first of all, a planarization material 9 (an embedded material) is applied on the whole surface over the cap film 5, and then the excessive planarization material 9 is removed from the surface of the cap film 5 by the dry etching. Next, as shown in FIG. 4F, after the anti-reflection coating 6 is formed again on the whole surface of the cap film 5 and the planarization material 9 filled in the through-holes 8, the photoresist 7 is applied on the anti-reflection coating 6.

In the next step, as shown in FIG. 4G, the exposure and the development are performed in order to form a wiring trench pattern 10 on the photoresist 7, and a resist pattern 7b is formed. The resist pattern 7b is used as an etching mask to dry-etch the anti-reflection coating 6, the cap film 5, the second insulating film 4, or the planarization material 9 filled in the through-hole 8.

After removing the resist pattern 7b, the anti-reflection coating 6, and the planarization material 9 left in the through-hole 8, the etch-stop film 3 at the bottom of the through-hole 8 is removed by the overall dry-etching. On the surface of the wiring trench pattern 10 and the exposed surface of the through-hole, a metal barrier film 11a with a laminated structure such as TaN/Ta (lower layer: tantalum nitride, upper layer: tantalum) is formed by the sputtering. On the metal barrier layer 11a, a copper thin film is formed by the sputtering. By the electroplating wherein the copper film is used as an electrode, copper 11b is deposited inside of the through-holes 8 and the wiring trench pattern 10. After this, the upper surface of the copper wiring 11 and the cap film 5 are planarized by CMP. Accordingly, the multi-level structure wiring having the dual-damascene structure is completed as shown in FIG. 4H. The etch-stop film 3, the second insulating film 4, the cap film 5 and the copper wiring 11 are defined as a second wiring layer 22 in the following discussion.

In the above-mentioned damascene process, it is general that the chemically amplified resist is used as the photoresist 7. As is well known, the chemically amplified resist is such that the acid generator included in the resist generates acid substances by light.

For instance, in case of the positive type of chemically amplified resist, the acid substance is reacts with a principal component of the resist such as an acrylic resin, and a protecting group for inhibiting from dissolving the resist in the developer is separated from the acrylic resin, so that the resist changes to a soluble structure in the developer. On the other hand, as for the negative type of chemically amplified resist, the acid substance reacts with the principal component of the resist such as the acrylic resin or the like, and a reaction group to dissolve the resist to the developer is separated from the acrylic resin, and then the acrylic resin from which the reaction group is separated is polymerized, so that the resist changes to an insoluble structure in the developer.

At the reaction of the acrylic resin and the acid substance, the acid substance is generated secondarily as an active substance (thus separated protect group or reaction group), so that the reaction to change the acrylic resin structure may be continuously accelerated at the exposed parts.

In the above-mentioned configuration, however, where the wiring trench pattern 100 is formed near to the through-hole 8, the resist poisoning is generated.

The resist poisoning is caused by the diffusion of a basic substance in the photoresist 7 through the second insulating film 4 or the through-hole 8; the basic substance based on a nitrogen component, such as amine, in the second insulating film 4 of carbon-dropped silicon dioxide film under the wiring trench pattern 10, or based on the nitrogen component included in the first insulating film 1, the etch-stop film 3, and the cap film 5, (those are defined as reaction inhibiting substances hereinafter).

Specifically, when the exposure is performed to form the wiring trench pattern 10, the reaction inhibiting substances, which are diffused in the photoresist 7 through the second insulating film 4 or the through-hole 8, neutralize acid substances generated from the acid generator. In result, the above continuously acid generating reaction is inhibited, and the above mentioned reaction for changing the acrylic resin structure is not accelerated fully at the exposed parts of the photoresist 7. This generates a poor development.

Accordingly, in case of use of the positive type chemically amplified resist, due to the generation of the resist poisoning, the resist to be dissolved at the development is not dissolved and remains. For instance, where a resist residual X is generated on the through-hole 8 at a bottom of the resist pattern 7b as shown in FIG. 5A, an etching residual 30 of the insulating film called a fence is generated on an upper periphery section of the through-hole 8 as shown in FIG. 5B. Additionally, where the resist residual Y is generated on allover the bottom of the resist pattern 7b as shown in FIG. 5C, the wiring trench pattern 31 is formed shallowly.

Meanwhile, in case of use of the negative type of chemically amplified resist, when the resist poisoning is generated, the resist to remain as the pattern (the bottom, in particular) becomes a soluble condition in the developer. When such condition appears on the resist pattern 7b formed near to the through-hole 8, there is a possibility to generate the resist pattern defective Z as shown in FIG. 5E, for example. In this case, the insulating film 32 for electrically separating two neighboring wirings is not formed as shown in FIG. 5F, so that the both wirings are short-circuited.

In either case, since the wiring trench pattern is not formed normally, the interconnection between the copper wiring 2 in the first wiring layer 21 and the copper wiring 11 in the second wiring layer 22 is failed, and the semiconductor device is defective. Additionally, where the second insulating film is formed by the low dielectric constant film as described above, it increases the occurrences of the resist poisoning, which is a serious problem.

To settle the problem, Japanese laid-open publication No. 2003-229481 discloses a method for eliminating the reaction inhibiting substances so that the object to be processed is subjected to the anneal processing, the UV exposure processing, the plasma processing, and organic solvent processing before forming the wiring trench pattern.

### SUMMARY OF THE INVENTION

When each process disclosed in the above-mentioned prior art is executed, however, there is a possibility that under-mentioned problems appear.

The annealing processing for heating a substrate (an object) to desorb the reaction inhibitor puts the substrate under heat stresses, so that deforming stresses might be accumulated in each insulating layer. The stresses thus accumulated would trigger a stress migration, and this might reduce the reliability of the wiring structure. Additionally, if the annealing processing is performed at comparatively low temperature in order to avoid the accumulation of the stresses, it takes too much time for the annealing processing.

On the other hand, an UV irradiation processing, when it is performed on the second insulating film 4 that is the low dielectric constant film of organic material, might change the property of the low dielectric constant film.

In addition, a plasma processing causes physical damages to a surface of the object, and deform the surf ace of the object not a little. In case of an organic solvent processing, the organic solvent permeates the low dielectric constant film with a rough film composition, and the organic component will be left in the low dielectric constant film. In this way, the organic component left in the insulating film becomes a factor reducing the wiring reliability due to the migration.

The invention is provided in consideration with the above-mentioned subjects, and has an object to provide the planarization material, and the anti-reflecting coating material without any trouble in the insulating film, and the method of manufacturing a semiconductor device using those materials.

In order to settle the above subjects, the invention adopts technical means as follows. A first invention is a planarization material to fill recesses of the object to be etched by using a resist pattern of the chemically amplified resist as an etching mask. The planarization material of the invention has a higher etching rate than that of the chemically amplified resist film, and contains a photo acid generator or a thermal acid generator.

The photo acid generator is preferable to contain at least one of an onium salt compound, a sulfonate ester compound, a halogenic system compound, and a sulfonate system compound. The thermal acid generator is preferable to contain at least a sulfonate ester compound.

The photo acid generator or the thermal acid generator for the planarization material is preferable to contain 0.1 to 10 wt % in proportion to a base polymer that is a principal component of the planarization material.

A second invention is an anti-reflection coating material to be applied just under the chemically amplified resist film. The anti-reflection coating material of the invention has a higher etching rate than the chemically amplified resist film, and contains a photo acid generator or a thermal acid generator.

The photo acid generator and the thermal acid generator for the anti-reflection coating material may be the same as those of the planarization material. The photo acid generator or the thermal acid generator for the anti-reflection coating material contains 0.1 to 10 wt % in proportion to a base polymer which is a principal component of the anti-reflection coating material.

On the other hand, the invention can provide a manufacturing method of a semiconductor device by using the planarization material and/or the anti-reflection coating film formation material.

The manufacturing method of the semiconductor device in the invention is to etch an object with recesses filled with the planarization material and/or an object with the anti-reflection coating by using the resist pattern of the chemically amplified resist film formed on the anti-reflection coating as a mask. The manufacturing method of the semiconductor device in the invention uses the planarization material and/or the anti-reflection coating material that has a higher etching rate than the chemically amplified resist film and contains the photo acid generator or the thermal acid generator.

In the manufacturing method of the semiconductor device in the invention, where the planarization material and/or the anti-reflection coating contain the photo acid generator, the acid substances are generated by exposing the material. Where the planarization material and/or the anti-reflection coating contain the thermal acid generator, the acid substances are generated by heating the material.

The invention can inhibit the diffusion of reaction inhibitors into the chemically amplified resist film; the reaction inhibitors trigger the resist poisoning. Therefore, it is possible to form the multi-level structure wiring with the dual-damascene structure precisely.

In the invention, while adding the flood exposure process or adding no further processes to the conventional manufacturing processes, for example, it is possible to block the generation of the reaction inhibitors in a very simple manner.

### BRIEF DESCRIPTION OF THE DRAWINGS

The present invention is illustrated by way of example, and not by way of limitation, in the figures of the accompanying drawings and in which like reference numerals refer to similar elements and in which:

FIGS. 1A to 1H are sectional views of a manufacturing process of a semiconductor device in a first embodiment.

FIGS. 2A to 2H are sectional views of a manufacturing process of a semiconductor device in a second embodiment.

FIG. 3 is a sectional view of a dual-damascene structure.

FIGS. 4A to 4H are sectional views of a conventional manufacturing process of a semiconductor device.

FIGS. 5A to 5F are views for explaining the resist poisoning.

### DETAILED DESCRIPTION OF THE PREFERRED EMBODIMENT

The invention is described with reference to specific embodiments thereof together with attached drawings.

### Embodiment 1

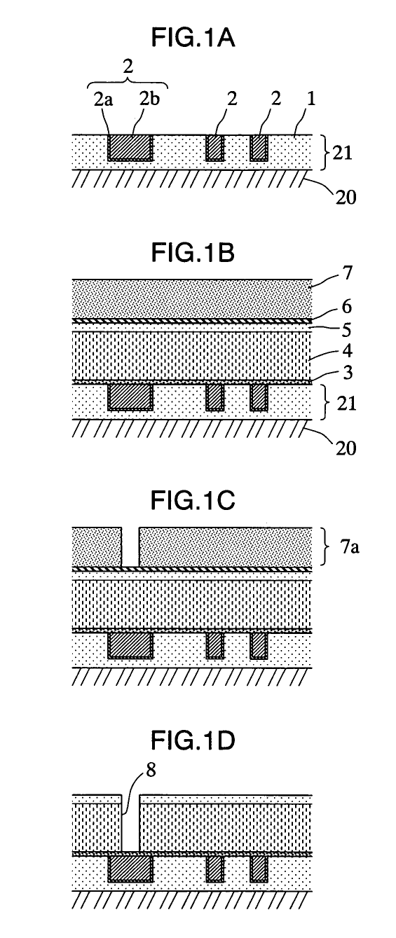

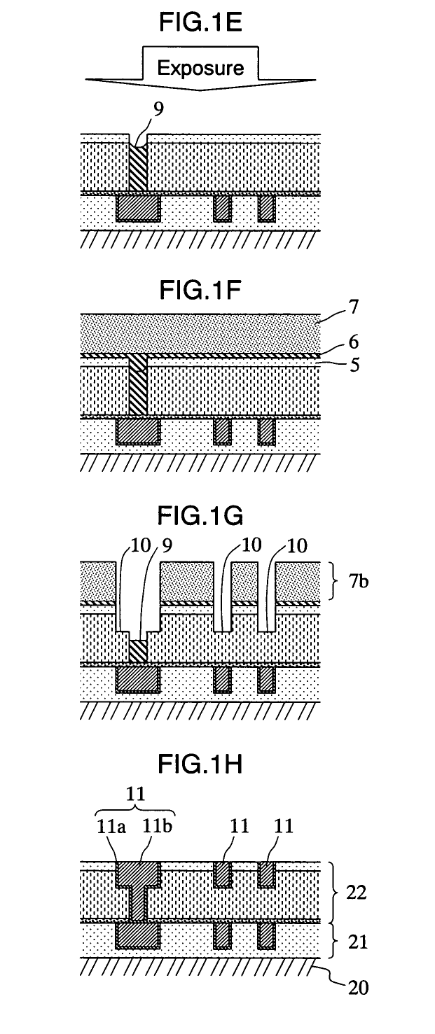

FIGS. 1A to 1H are sectional views of a manufacturing process of a semiconductor device using a planarization material in the present invention.

The planarization material to be used in the invention may include a non-photosensitive base polymer as a principal component, and also include at least one photo acid generator of an onium salt compound, a sulfonate salt compound, a halogenic system compound, or a sulfonate system compound. The material of the base polymer is not limited in particular, but may have a higher etching rate than that of the chemically amplified resist film applied on the planarization material For instance, it may use the base polymer that is used as the conventional planarization material.

The photo acid generator should be a material for generating acid substances when KrF laser, ArF laser, or F₂ laser is used as an exposure source. Accordingly, following materials can be used: phthalimide-trifluoromethanesulfonate, dinitorobenzyltosylate, n-decyledisulfone, naphthylimide-trifluoromethanesphonate, diphenyliodosalt-hexafluorophosphate, diphenyliodosalt-hexafluoroarsenate, diphyenyliodosalt-hexafluoroantimonate, diphenyl-paramethoxyphenyltriflate, diphenyl-paratoluenyltriflate, dipheynyl-para-t-butylphenyltriflate, dipheynyl-paraisobutylpheyltriflate, triphenylsulfonium-hexafluoroarsenate, triphyenylsulfonium-hexafluorophophate, triphenylsulfonium-triflate, dibutylnaphthylsulfonium-triflate, and the like.

The photo acid generator is preferable to contain 0.1 to 10 wt % in proportion to the base polymer. If the content is less than 0.1 wt %, the amount of the acid substance generation becomes small, and it is hard to obtain after-mentioned effects. Contrarily, if the content is over 10 wt %, the amount of the acid substance generation exceeds, and there is a possibility that the acid substance acts on the chemically amplified resist.

As for the above planarization material, the degree of the viscosity to apply the material is adjusted to 3×10⁻³ Pa.s or less so as to allow the material to fill the though-hole of 90 nm in diameter.

The manufacturing process of the semiconductor device using the above planarization material is discussed hereinafter.

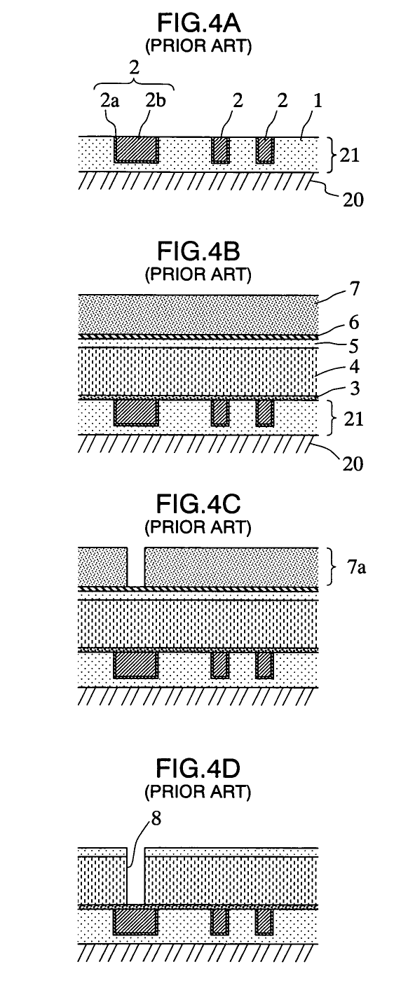

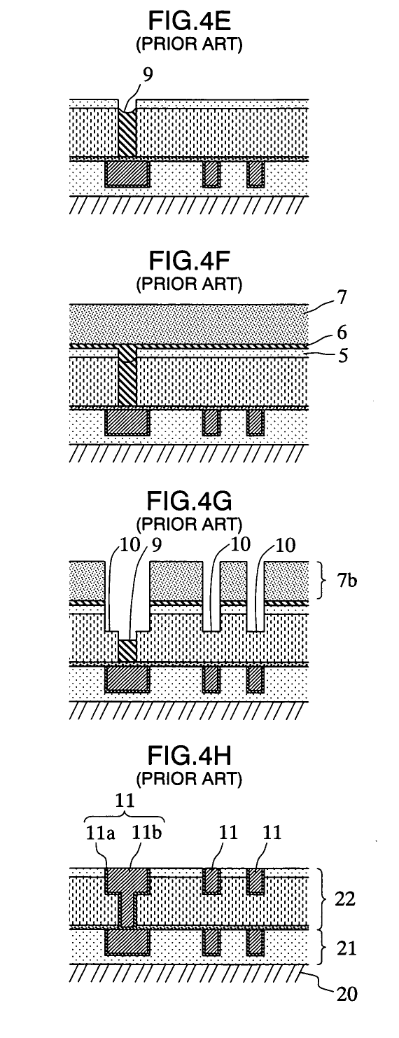

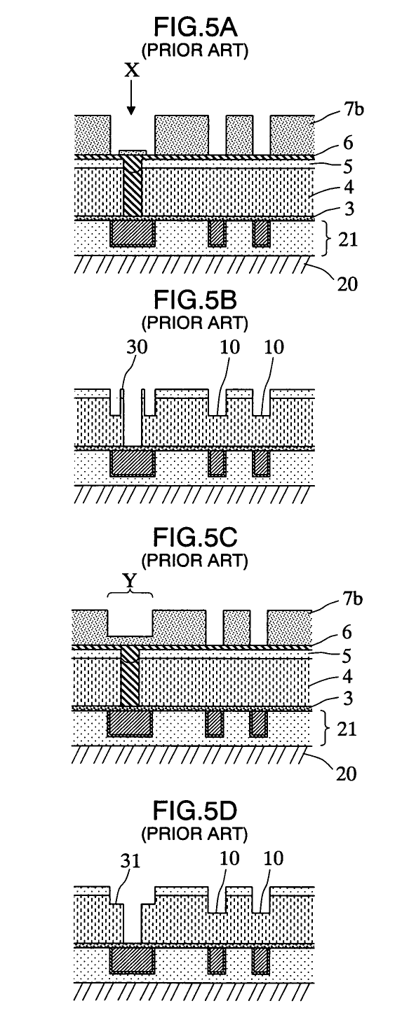

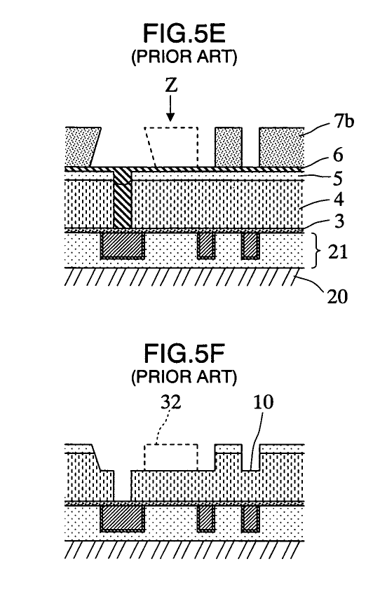

As shown in FIGS. 1A to 1D, first of all, a first wiring trench pattern is formed in a first insulating film 1 of the silicon dioxide film on a semiconductor substrate 20 such as a silicon substrate, by the photolithography and the dry etching, in the same way as the conventional manufacturing process in connection with FIGS. 4A to 4H. Within the wiring trench pattern, a barrier metal layer 2a of Tantalum Nitride and Tantalum and a first metal wiring 2 of copper 2b are formed by CMP (FIG. 1A).

On the first insulating film 1 and the first metal wiring 2, an etch-stop film 3 of the silicon carbon nitride film is deposited in 50 nm by CVD. Additionally, a second insulating film 4 is deposited in 450 nm, which is a low-dielectric constant film made of inorganic or organic material having 3 or less dielectric constant, such as carbon-dropped silicon dioxide film. On the second insulating film 4, a cap film 5 of the silicon dioxide film is deposited in 50 nm by CVD. The material of the etch-stop film 3 may be hard to be etched by the etching gas at the dry etching of the second insulating film 4, and the material of the cap film 5 may be hard to be etched by the etching gas at the dry etching of the etch-stop film 3. That is to say, the materials of the etch-stop film 3 and the cap film 5 may be decided in accordance with the material of the second insulating film 4.

Moreover, an anti-reflection coating 6 made of inorganic or organic material is applied thereon. On a chemically amplified resist film 7 applied on the anti-reflection coating 6, a resist pattern 7a is formed by the photolisography (FIG. 1B and FIG. 1C). The anti-reflection coating 6, the cap film 5, and the second insulating film 4 are removed from the place where through-holes 8 are to be formed by the dray etching, and through-holes 8 are formed (FIG. 1D). Then, the resist pattern 7a and the anti-reflection coating 6 are removed by the ashing. Besides, the material of the chemically amplified type resist is not limited in particular, but it may be the one that the acid generator included in the resist generates the acid substance by light and the resist changes to be soluble (or insoluble) in the developer due to the reaction of the acid substance.

On the substrate on which the through-holes 8 are formed, the planarization material 9 is applied and filled in the through-holes 8, and then the excessive material are removed from the surface by the dry etching.

A next step in the manufacturing method of the invention is different from the conventional one, because it is configured as shown in FIG. 1E that, after the flood exposure or at least the exposure to the planarization material 9 embedded in the through-holes 8, the photo acid generator included in the planarization material 9 generates the acid substances.

Then, on the cap film 5 and the planarization material 9 filled in the through-holes 8, the anti-reflection coating 6 and the chemically amplified type photoresist 7 are applied (FIG. 1F). After that, in order to form a desired wiring trench pattern 10, a resist pattern 7b is formed by the photolithography.

By using the resist pattern 7b as an etching mask, the anti-reflection coating 6, the cap film 5, and the second insulating film 4 are dry-etched, and then the desired wiring trench pattern 10 is formed (FIG. 1G).

The subsequent processes are such as for (a) removing and cleaning the planarization material 9 left in the through-holes 8, the resist pattern 7b and the anti-reflection coating 6, (b) removing the etch-stop film 6 at the bottom of the through-holes 8 by the allover etching, (c) forming and polishing the upper surface of the second metal wiring 11 of the metal barrier layer 11a of TaN/Ta and the copper 11b, and (d) polishing a top surface of a substrate by CMP; those processes are the same as the conventional manufacturing processes (FIG. 1H).

As discussed above, in the manufacturing method of the invention, it is configured that, before applying the chemically amplified resist film 7 for forming the wiring trench pattern 10 in the second wiring layer 22, the acid substance is generated in the planarization material filled in the through-holes 8. Hence, the reaction inhibitors, which used to be diffused in the chemically amplified resist film 7 through the through-holes 8 in the conventional way, is neutralized by the acid substance generated in the planarization material 9, so that the reaction inhibitors could not diffused in the chemically amplified resist film 7. In result, it is possible to inhibit the occurrence of the resist poisoning, and the multi-level structure wiring with the dual-damascene can be formed in good condition.

In the invention, only the flood exposure is added to the conventional general processes. That is, the invention does not complicate the manufacturing process particularly, and can carry out the manufacturing method using the conventional production unit. In addition, the manufacturing method of the invention does not cause any damages and stresses to a to-be-processed object on the semiconductor substrate.

In the above-mentioned embodiment, the planarization material is exposed before the formation of the anti-reflection coating 6, but it is nevertheless to say that the exposure may be performed at any stage before the application of the chemically amplified resist film 7.

### Embodiment 2

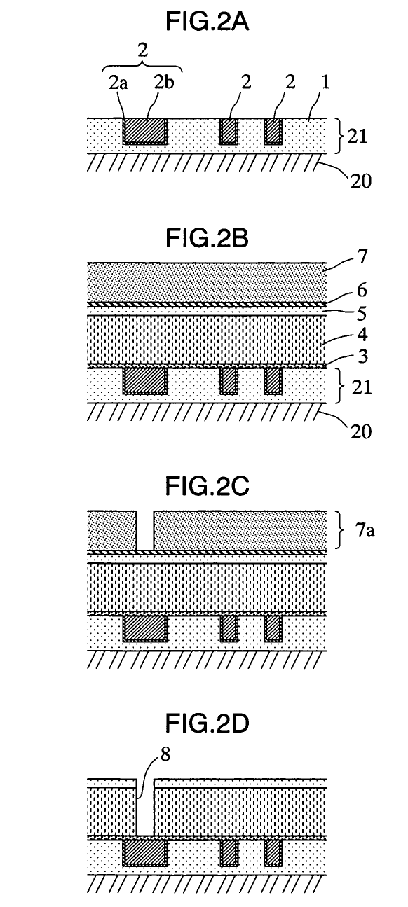

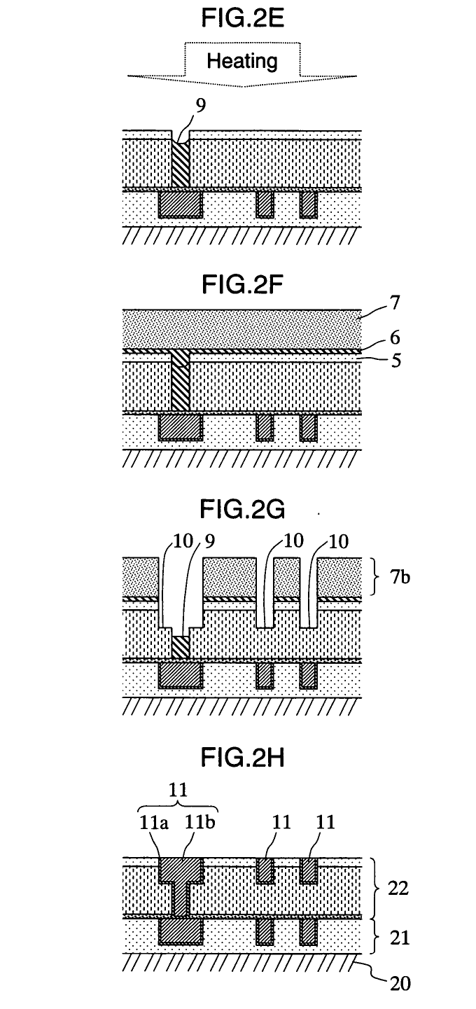

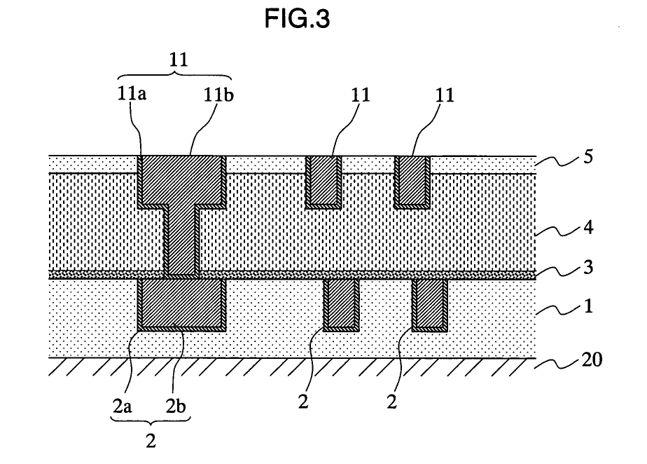

FIGS. 2A to 2H are sectional views of a manufacturing process of a semiconductor device using another planarization material in the present invention.

The planarization material to be used in this embodiment contains non-photosensitive base polymer as a principal component, and contains a thermal acid generator made of a sulfonate compound. The material of the base polymer is not limited in particular, but may have a higher etching rate than that of the chemically amplified resist film applied on the planarization material. For instance, it may use the base polymer that is used as the conventional planarization material.

The thermal acid generator may be the one that generates acid substances at the application of heat. For instance, it can use cyclohexanetoluensulfonate, cyclohexanepropylsulfonate, cyclohexanemethylsulfonate, cyclohexaneoctylesulfonate, cyclohexanecanfosulfonate, or the like.

The thermal acid generator is preferable to contain 0.1 to 10 wt % in proportion to the base polymer. If the content is less than 0.1 wt %, the amount of the acid substance generation becomes small, and it is hard to obtain after-mentioned effects. Contrarily, if the content is over 10 wt %, the amount of the acid substance generation exceeds, and there is a possibility that the acid substance acts on the chemically amplified resist.

As for the above planarization material, the degree of the viscosity to apply the material is adjusted to 3×10⁻³ Pa.s or less so as to allow the material to fill the though-hole of 90 nm in diameter.

The manufacturing process of the semiconductor device using the above planarization material is discussed hereinafter.

Like the first embodiment, according to the processes as shown in FIGS. 1A to 1D, the through-holes 8 are formed (FIGS. 2A to 2D). The material of the chemically amplified type resist, which is used in this embodiment, may be the one that the acid generator included in the resist generates the acid substance by light and the resist changes to be soluble (or insoluble) in the developer due to the reaction of the acid substance.

On the substrate on which the through-holes 8 are formed, the planarization material 9 is applied and filled in the through-holes 8, and then the excessive material are removed from the surface by the dry etching.

A next process in the manufacturing method of the embodiment is different from the first embodiment, and it is configured as shown in FIG. 2E that, heating the planarization material 9 embedded in the through-holes 8 allows the thermal acid generator contained in the planarization material 9 to generate the acid substances.

Then, on the cap film 5 and the planarization material 9 filled in the through-holes 8, the anti-reflection coating 6 and the chemically amplified type photoresist 7 are applied (FIG. 2F). After that, in order to form the desired wiring trench pattern 10, the resist pattern 7b is formed by the photolithography.

By the dry-etching using the resist pattern 7b as an etching mask, the anti-reflection coating 6, the cap film 5, and the second insulating film 4 are dry-etched, and then the desired wiring trench pattern 10 is formed (FIG. 2G).

The subsequent processes are such as for (a) removing and cleaning the planarization material 9 left in the through-holes 8, the resist pattern 7b and the anti-reflection coating 6, (b) removing the etch-stop film 6 at the bottom of the through-holes 8 by the allover etching, (c) forming and polishing the upper surface of the second metal wiring 11 of the metal barrier layer 11a of TaN/Ta and the copper 11b, and (d) polishing a top surface of a substrate by CMP; those processes are the same as the conventional manufacturing processes (FIG. 2H).

As discussed above, in the manufacturing method of the invention, it is configured that, before applying the chemically amplified resist film 7 for forming the wiring trench pattern 10 in the second wiring layer 22, the acid substance is generated in the planarization material filled in the through-holes 8. Hence, the reaction inhibitors, which used to be diffused in the chemically amplified resist film 7 through the through-holes 8 in the conventional way, is neutralized by the acid substance generated in the planarization material 9, so that the reaction inhibitors could not diffused in the chemically amplified resist film 7. In result, it is possible to inhibit the occurrence of the resist poisoning, and the multi-level structure wiring with the dual-damascene can be formed in good condition.

In the invention, only the heating process is added to the conventional general processes after the application of the planarization material. That is, the manufacturing process of the invention is not more complicate than conventional way, and can carry out the manufacturing method using the conventional production unit. In addition, since the heat temperature is approximately 100° C., the manufacturing method of the invention does not cause any damages and stresses to a to-be-processed object on the semiconductor substrate.

In the above-mentioned embodiment, the planarization material is heated before the formation of the anti-reflection coating 6, but it is nevertheless to say that the heating may be performed at any stage before the chemically amplified resist film 7 is exposed and developed. The pre-bake before the application of the resist can be combined with the heating for generating the acid substances. In this case, without increasing the number of processes of the conventional processes, the occurrence of the resist poisoning can be inhibited.

In the above discussion, at the formation of the dual damascene structure, the planarization material filled in the through-holes 8 contains the acid generator. The material, if it contains the acid generator like the planarization material, can be used as the formation material of the anti-reflection coating 6. That is to say, the invention can provide the material for forming the anti-reflection coating that the above-mentioned photo acid generator or thermal acid generator is added to the well-known base polymer using as the anti-reflection coating material in the above-mentioned proportion.

The anti-reflection coating material also can inhibit the diffusion of the reaction inhibitors into the chemically amplified resist film 7, in the same way as the planarization material of the invention.

In the above embodiments, in order to be able to uniformly apply the chemically amplified resist film 7 for forming the wiring trench pattern 10 of the second wiring layer 22, the anti-reflection coating 6 is applied after the planarization material 9 is filled in the through-holes 8. In this case, the formation material of the planarization material 9 may be the same as that of the anti-reflection coating 6, and embedding the planarization material 9 in the through-holes 8 and forming the anti-reflection film 6 are not always performed separately; both steps are completed by one application of the material.

In such manufacturing processes, it is possible to inhibit the diffusion of the reaction inhibitors into the chemically amplified resist film 7, like the aforementioned embodiment.

The invention has an effect that the resist poisoning can be inhibited, and is useful for forming the multi-level structure wiring with the dual-damascene structure.

1. A planarization material to fill objective recesses to be etched by using a resist pattern of chemically amplified resist film as a mask,
which characterized by that an etching rate is higher than the chemically amplified resist film, and
containing a photo acid generator or a thermal acid generator.

2. A planarization material according to claim 1, wherein the photo acid generator contains at least one of an onium salt compound, a sulfonate ester compound, a halogenic system compound, and a sulfonate system compound.

3. A planarization material according to claim 1, wherein the thermal acid generator contains at least a sulfonate ester compound.

4. A planarization material according to claim 2 or claim 3, wherein the photo acid generator or the thermal acid generator contains 0.1 to 10 wt % in proportion to a base polymer that is a principal component of the planarization material.

5. An anti-reflection coating material to be applied just under the chemically amplified resist film,
which is characterized that the formation material has a higher etching rate than the chemically amplified resist film, and
contains a photo acid generator or a thermal acid generator.

6. An anti-reflection coating material according to claim 5, wherein the photo acid generator contains at least one of an onium salt compound, a sulfonate ester compound, a halogenic system compound, and a sulfonate system compound.

7. An anti-reflection coating material according to claim 5, wherein the thermal acid generator contains at least a sulfonate ester compound.

8. An anti-reflection coating material according to claim 6 or claim 7, wherein the photo acid generator or the thermal acid generator contains 0.1 to 10 wt % in proportion to a base polymer which is a principal component of the anti-reflection coating material.

9. A manufacturing method of a semiconductor device, which fills objective recesses with a planarization material and etches specific parts including the objective recesses using a resist pattern of a chemically amplified resist film as a mask, the method comprises steps of:
filling the recesses with the planarization material that has a higher etching rate than the chemically amplified resist film and contains an acid generator;
generating an acid on the filled planarization material;
forming the chemically amplified resist film;
exposing and developing the chemically amplified resist film; and etching by using the exposed and developed resist pattern as a mask.

10. A manufacturing method of a semiconductor device according to claim 9, wherein the acid generator is a photo acid generator, and the step of generating the acid is a step of generating an acid substance by exposing the planarization material.

11. A manufacturing method of a semiconductor device according to claim 9, wherein the acid generator is a thermal acid generator, and the step of generating the acid is a step of generating an acid substance by heating the planarization material.

12. A manufacturing method of a semiconductor device, which forms an anti-reflection coating on an object and etches the object using a resist pattern of a chemically amplified resist film formed on the anti-reflection coating as a mask, the method comprises steps of:
forming on the object the anti-reflection coating made of an anti-reflection coating material that has a higher etching rate than the chemically amplified resist film and contains an acid generator;
generating an acid on the anti-reflection coating;
forming the chemically amplified resist film;
exposing and developing the chemically amplified resist film; and
etching by using the exposed and developed resist pattern as a mask.

13. A manufacturing method of a semiconductor device according to claim 12, wherein the acid generator is a photo acid generator, and the step of generating the acid is a step of generating an acid substance by exposing the anti-reflection coating.

14. A manufacturing method of a semiconductor device according to claim 12, wherein the acid generator is a thermal acid generator, and the step of generating the acid is a step of generating an acid substance by heating the anti-reflection coating.

15. A manufacturing method of a semiconductor device, which fills objective recesses with a planarization material, forms a anti-reflection coating film on the planarization material, and etches specific parts including the objective recesses by using a resist pattern of a chemically amplified resist film formed on the anti-reflection coating film as a mask, the method comprising steps of:
filling the recesses with the planarization material that has a higher etching rate than the chemically amplified resist film and contains an acid generator;
forming on the planarization material the anti-reflection coating film made of a anti-reflection coating material that has a higher etching rate than the chemically amplified resist film and contains an acid generator;
generating an acid on the filled planarization material and the anti-reflection coating material;
forming the chemically amplified resist film;
exposing and developing the chemically amplified resist film; and
etching by using the exposed and developed resist pattern as a mask.

16. A manufacturing method of a semiconductor device according to claim 15, wherein the planarization material and the anti-reflection coating material are the same material.

17. A manufacturing method of a semiconductor device according to claim 16, wherein the step of filling with the planarization material and the step of forming the anti-reflection coating are performed simultaneously.
